(19) United States
(12) Patent Application Publication
(10) Pub. No.: US 2009/0166716 A1
(43) Pub. Date: Jul. 2, 2009

(54) SEMICONDUCTOR DEVICE AND METHOD FOR MANUFACTURING THE SAME

(76) Inventor: Cheol-Soo Jo, Gochang-gun (KR)

Correspondence Address: SHERR & VAUGHN, PLLC, 620 HERNDON PARKWAY, SUITE 200, HERNDON, VA, 20170, US

(21) Appl. No.: 12/344,505

(22) Filed: Dec. 27, 2008

(30) Foreign Application Priority Data
Dec. 27, 2007 (KR) 10-2007-0138486

(51) Int. Cl. H01L 29/792; H01L 21/336

(52) U.S. Cl. 257/324; 438/287; 257/E29.309; 257/E21.422

(57) ABSTRACT

A semiconductor device includes a first oxide-nitride-oxide (ONO) layer in which a block oxide, a tunnel oxide and a trap nitride are stacked sequentially on one side of a semiconductor substrate; a second oxide-nitride-oxide (ONO) layer in which the block oxide, the tunnel oxide and the trap nitride are stacked sequentially on the other side of the semiconductor substrate; a third oxide formed between the first ONO layer and the second ONO layer; a silicon gate formed on the first ONO layer, the second ONO layer and the third oxide; and a source region and a drain region formed on the surface of the semiconductor substrate of both sides of the silicon gate.

The present application claims priority under 35 U.S.C. 119 to Korean Patent Application No. 10-2007-0138486 (filed on Dec. 27, 2007), which is hereby incorporated by reference in its entirety.

### BACKGROUND

With the recent multi-function and miniaturization of electronic devices, there is a demand for increasing the fineness of semiconductor integration circuits. A general non-volatile semiconductor memory such as, for example, an electrically erasable programmable read only memory (EEPROM), a flash memory, or the like has a dual gate structure where a floating gate and a control gate are formed with a thin dielectric film in-between. However, because of the complexity of the manufacturing process for the dual-gate structure, a single gate structure non-volatile semiconductor memory may be preferable instead of the dual gate structure.

One related type of single gate structure non-volatile semiconductor memories includes a silicon oxide nitride oxide silicon (SONOS) type memory. FIG. 1 shows a related multi-level silicon oxide nitride oxide silicon (SONOS) type non-volatile memory structure. Referring to FIG. 1, an ONO layer in which a tunnel oxide 20, a trap nitride 25 and a block oxide 30 are deposited sequentially is formed on a semiconductor substrate 10. A poly silicon gate 35 is formed on the top surface of the ONO layer 20, 25 and 30, and impurity injection regions (for example, source or drain) are formed on the semiconductor substrate 10 on both sides of the poly silicon gate 35.

In the illustrated structure, when testing a program operation, an erase operation, and the endurance and retention of the multi-level SONOS type non-volatile memory, there is no bit boundary between a first bit cell and a second bit cell so that it is difficult to determine whether the first bit cell or the second bit cell is in the program state or in the erase state by charges trapped in the trap nitride 25, which is an undesirable characteristic.

### SUMMARY

Embodiments relate to a semiconductor device which allows clearer determination of whether the multi-cell is in a program state or in an erase state at the time of a program or erase operation; and a method for manufacturing the same.

Embodiments relate to a semiconductor device that includes: a first oxide-nitride-oxide (ONO) layer in which a block oxide, a tunnel oxide and a trap nitride are stacked on one side of a semiconductor substrate; a second oxide-nitride-oxide (ONO) layer in which the block oxide, the tunnel oxide and the trap nitride are stacked on the other side of the semiconductor substrate; a third oxide formed between the first ONO layer and the second ONO layer; a silicon gate formed on the first ONO layer, the second ONO layer and the third oxide; and a source region and a drain region formed on the surface of the semiconductor substrate on both sides of the silicon gate.

Embodiments relate to a method for manufacturing a semiconductor device that includes: forming a oxide-nitride-oxide (ONO) layer by stacking a block oxide, a tunnel oxide and a trap nitride on a semiconductor substrate; separating the ONO layer into a first ONO layer and a second ONO layer by selectively etching the block oxide, the trap nitride and the tunnel oxide; forming a third oxide between the first ONO layer and the second ONO layer; forming a silicon gate on the first ONO layer, the second ONO layer and the third oxide; and forming a source region and a drain region on the surface of the semiconductor substrate on both sides of the silicon gate.

Embodiments relate to a multi-level SONOS type non-volatile memory structure which isolates the trap nitride between the multi-level cells so that the program state or erase state of the respective multi-level cells can be more clearly distinguished at the time of a program operation or an erase operation of the multi-level cells. Doing so may reduce or prevent malfunctions of the multi-level SONOS type non-volatile memory and enhance the reliability of the SONOS type non-volatile memory.

### DRAWINGS

FIG. 1 shows a related multi-level SONOS type non-volatile memory structure.

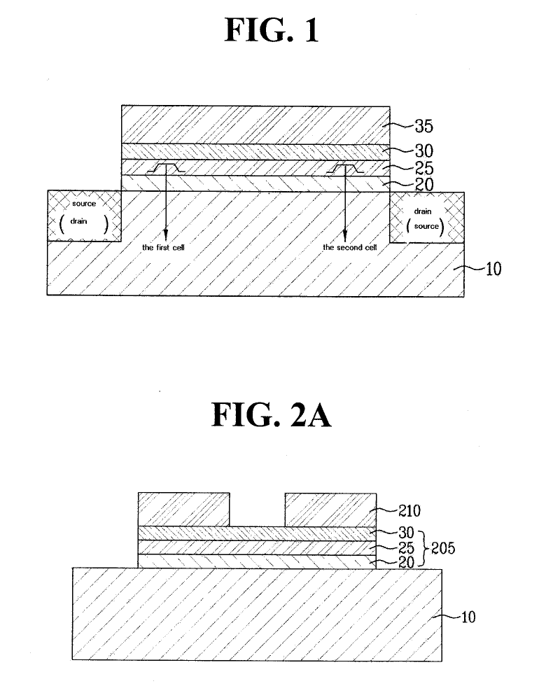

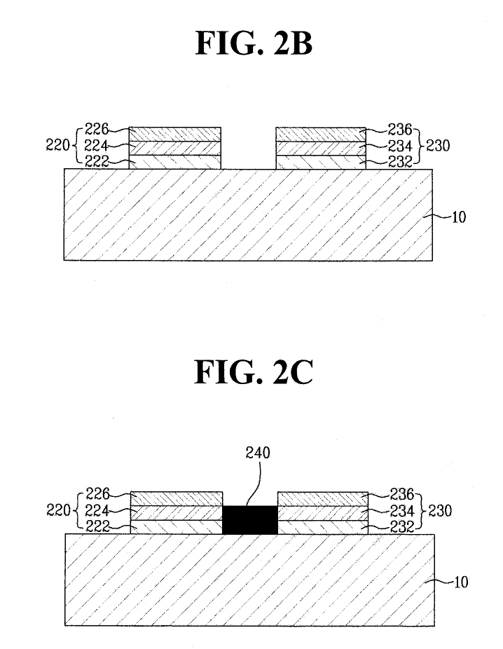

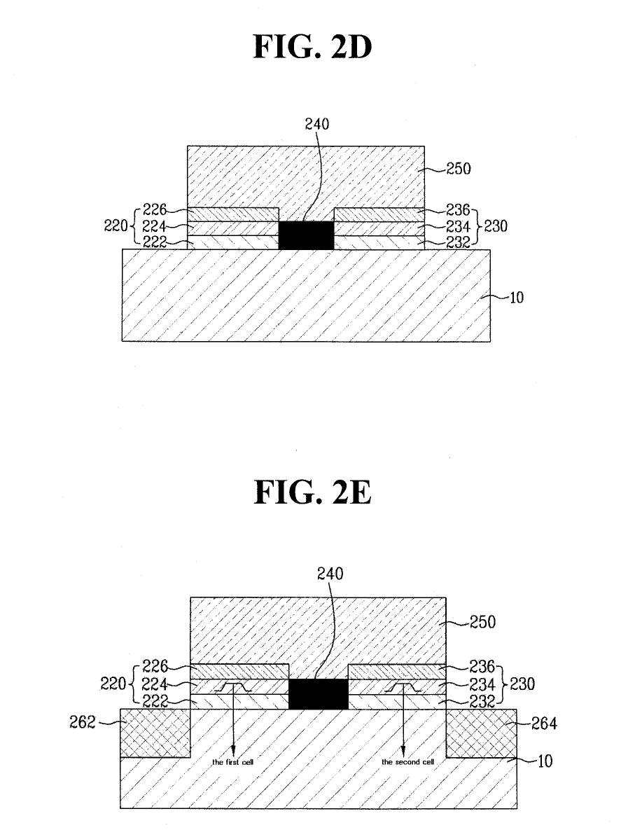

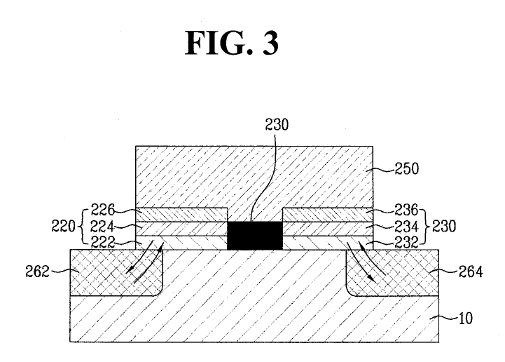

Example FIGS. 2A to 2E depict cross-sectional views showing manufacturing processes of a multi-level SONOS type non-volatile memory according to embodiments.

Example FIG. 3 shows a FN tunneling operation method of a multi-level SONOS type non-volatile memory of FIG. 2E.

### DESCRIPTION

Example FIGS. 2A to 2E are cross-sectional views showing manufacturing processes of a multi-level SONOS type non-volatile memory according to embodiments. As shown in example FIG. 2A, an ONO layer 205, in which a tunnel oxide 20, a trap nitride 25 and a block oxide 30 are sequentially stacked, is formed on, or over, a silicon semiconductor substrate 10 and a photo resist pattern 210 may be formed on, or over, the tunnel oxide 30 through, for example, a photolithography process. In order to separate the ONO layer 205 in forming the multi-level cell, the photoresist pattern 210 is patterned. For example, the photoresist pattern 210 may be patterned as shown in example FIG. 2A, in order to separate the ONO layer 205 into two parts.

Next, as shown in example FIG. 2B, the tunnel oxide 30, trap nitride 25 and block oxide 20 may be selectively etched according to the photoresist pattern 210 to separate the ONO layer 205 into a first ONO layer 220 and a second ONO layer 230 on, or over, the semiconductor substrate 10. The distance of separation between the first ONO layer 220 and the second ONO layer 230 may be a variety of distance such as, for example, between about 0.13 μm to 0.26 μm. The first ONO layer 220 may include a block oxide 222, a trap nitride 224 and a tunnel oxide 226, and the second ONO layer 230 may also include a block oxide 232, a trap nitride 234 and a tunnel oxide 236.

After forming the first ONO layer 220 and second ONO layer 230 separated from each other, the remaining photoresist pattern 210 may be removed such as, for example, through asher and strip processes. Next, as shown in example FIG. 2C, a third oxide 240 may be formed between the first ONO layer 220 and the second ONO layer 230. The third oxide 240 may be formed to be substantially equal to or higher than the trap oxide nitride 224 of the first ONO layer 220 and the trap nitride 234 of the second ONO layer 230 such as, for example, through an oxidation process. When performing an oxidation process for forming the third oxide film 240, it may be beneficial to additionally remove mobile charges using, for example, HCl gas.

Forming the third oxide 240 to be higher than the trap oxide nitride 224 of the first ONO layer 220 and the trap nitride 234 of the second ONO layer 230, may be beneficial for a variety of reasons. First, doing so helps to isolate the trap nitride 224 of the first ONO layer 220 from the trap nitride 234 of the second ONO layer 230. Secondly, doing so helps reduce or prevent stress between a silicon gate 250 and the trap nitrides 224 and 234 in a subsequent process where the silicon gate 250 of example FIG. 2D is formed. Thirdly, if the third oxide 240 is formed to be lower than the respective block oxides 222 and 232 of the first ONO layer 220 and second ONO layer 230, the third oxide 240 may not endure the relatively high voltage applied at the time of program operations or erase operations which may result in a hot carrier and tunneling being generated from the third oxide 240, such that a parasitic transistor may be formed.

Next, as shown in example FIG. 2D, a silicon gate 250 may be formed on, or over, the first ONO layer 220, the second ONO layer 230 and the third oxide 240. As shown in example FIG. 2E, impurities (Extrinsic, for example, N or P type impurities) may be implanted into the surface of the semiconductor substrate 10 of respective sides of the silicon gate 250, forming impurity implantation regions 262 and 264. The impurity implantation regions 262 and 264 may be drain or source regions depending on operation bias voltage.

Example FIG. 2E is a cross-sectional view of a multi-level SONOS type non-volatile memory according to embodiments. Referring to example FIG. 2E, the multi-level SONOS type non-volatile memory may include a first ONO layer 220, a second ONO layer 230, a third oxide 240, a silicon gate 250, a source region 262 and a drain region 264. The first ONO layer 220 may include a block oxide 222, a trap nitride 224 and a tunnel oxide 226 sequentially stacked on, or over, one side of a semiconductor substrate 10. The second ONO layer 230 may include a block oxide 232, a trap nitride 234 and a tunnel oxide 236 sequentially stacked on, or over, the other side of the semiconductor substrate 10.

The spacing distance between the first ONO layer 220 and the second ONO layer 230 on the semiconductor substrate 10 may, for example, be between about 0.13 μm to about 0.26 μm but other spacing distances are contemplated as well. The third oxide 240 may be formed between the first ONO layer 220 and the second ONO layer 230 and may be formed to be higher than or substantially equal to the height of the trap nitride 224 of the first ONO layer 220 stacked on, or over, the semiconductor substrate 10 and the height of the trap nitride 234 of the second ONO layer 230 stacked on, or over, the semiconductor substrate 10. The silicon gate 250 may be formed on, or over, the first ONO layer 220, the second ONO layer 230 and the third oxide 240. The source region 262 and drain region 264 may be formed on the surface of the semiconductor substrate 10 on both sides of the silicon gate 250.

A multi-level SONOS type non-volatile memory of example FIG. 2E can perform a program operation or an erase operation based on a preset bias condition. In other words, the multi-level SONOS type non-volatile memory may perform a program operation on the first ONO layer 220 or the second ONO layer 230 by a channel hot electron injection (CHEI) method, for example. Also, the multi-level SONOS type non-volatile memory can perform an erase operation on the first ONO layer 220 or the second ONO layer 230 by a hot hole injection (HHI) method, for example. In the structure of example FIG. 2E, the first ONO layer 220 may be defined as a first cell and the second ONO layer 230 may be defined as a second cell.

The program operation on the first cell or the second cell may be performed under the bias conditions that a positive voltage is applied to the silicon gate 250, the positive voltage and a ground voltage is applied to the source region 262, and the positive voltage and the ground voltage is applied to the drain region 264. For example, in order to perform the program operation, the bias conditions may be set such that the positive voltage is first applied to the silicon gate 250 and drain region 264, and the ground voltage (for example, 0V) is applied to the source region 262. Under these bias conditions, channel electrons may be accelerated by a horizontal electric field formed in the direction from the source region 262 to the drain region 264 to be hot electrons around the drain region 264, to leap over potential barriers of the first block oxide 232 of the second ONO layer 230 and to be trapped by a trap level of the trap nitride 234 of the second ONO layer 230, such that the second cell is programmed.

In the alternative, if the bias conditions are set such that the positive voltage is applied to the silicon gate 250 and source region 262, and the ground voltage (for example, 0V) is applied to the drain region 264, the first cell may be programmed.

The erase operation on the first cell or the second cell may be performed under the bias conditions that a negative voltage is applied to the silicon gate 250, one of the positive voltage and ground voltage is applied to the source region 262, and the other of the positive voltage and the ground voltage is applied to the drain region 264. For example, in order to perform the erase operation, the bias conditions may be set such that the negative voltage is applied to the silicon gate 250, the positive voltage is applied to the drain region 264, and the ground voltage (for example, 0V) is applied to the source region 262. Under these bias conditions, a depletion region may be formed on the drain region 264 by high electromagnetic fields formed between the drain region 264 and the silicon gate 250, and electron hole pairs are formed on the depletion region by band to band tunneling.

The generated electrons may be discharged into the drain region 264, and the generated holes may be accelerated by side electric fields formed on the depletion region to be hot holes, to leap over potential barriers of the first block oxide 232 of the second ONO layer 230 and to be trapped by a trap level of the trap nitride 234 of the second ONO layer 230, such that the second cell is erased. In the alternative, if the bias conditions are set such that the negative voltage is applied to the silicon gate 250, the positive voltage is applied to the source region 262, and the ground voltage (for example, 0V) is applied to the drain region 264, the first cell may be erased.

The respective trap nitrides 224 and 234 of the first ONO layer 220 and the second ONO layer 230 of the multi-level SONOS type non-volatile memory of example FIG. 2E may be isolated by the third oxide 240. Therefore, at the time of the program operation or the erase operation described above, the electrons or holes trapped in the first cell or the second cell may be isolated from each other so that the capability to distinguish between the program operation and the erase operation of the multi-level cell can be improved.

Example FIG. 3 shows a Fowler-Nordheim (FN) tunneling operation method of a multi-level SONOS type non-volatile memory such as, for example, the memory of FIG. 2E. Referring to example FIG. 3, the program operation on the second cell may be performed under the bias conditions that positive voltage is applied to the silicon gate 250, negative voltage is applied to any one of the source region 262 and the drain region 264, and any one of the source region 262 and the drain region 264 is floated. Also, the erase operation on the first cell or the second cell may be performed under the bias conditions that positive voltage is applied to the silicon gate 250, positive voltage is applied to any one of the source region 262 and the drain region 264, and any one of the source region 262 and the drain region 264 is floated.

When a program operation or an erase operation occurs by means of the FN tunneling operation method, a channel or a junction may not be formed between the source region 262 and the drain region 264 by floating any one of the source region and the drain region, such that the first cell and the second cell can be substantially isolated from each other. Thus, malfunctions of the multi-level SONOS type non-volatile memory during a program operation or an erase operation can be prevented due to the substantial isolation between the cells.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. A semiconductor device, comprising:
a oxide-nitride-oxide (ONO) layer in which a block oxide, a trap nitride, and a tunnel oxide are stacked sequentially over one side of a semiconductor substrate;
a second oxide-nitride-oxide (ONO) layer in which the block oxide, the trap nitride, and the tunnel oxide are stacked sequentially over another side of the semiconductor substrate;
a third oxide formed between the first ONO layer and the second ONO layer;
a silicon gate formed over the first ONO layer, the second ONO layer and the third oxide; and
a source region and a drain region formed on a surface of the semiconductor substrate on respective sides of the silicon gate.

2. The semiconductor device according to claim 1, wherein the third oxide is formed to be higher than a height of the trap nitride of the first ONO layer stacked over the semiconductor substrate and a height of the trap nitride of the second ONO layer stacked over the semiconductor substrate.

3. The semiconductor device according to claim 1, wherein the third oxide includes a first top surface having a height higher than a second top surface of the trap nitride of the first ONO layer.

4. The semiconductor device according to claim 1, wherein the third oxide includes a first top surface having a height higher than a second top surface of the trap nitride of the second ONO layer.

5. The semiconductor device according to claim 1, wherein the third oxide is formed to be substantially equal to a height of the trap nitride of the first ONO layer stacked over the semiconductor substrate and the height of the trap nitride of the second ONO layer stacked over the semiconductor substrate.

6. The semiconductor device according to claim 1, wherein the third oxide includes a first top surface having a height substantially equal to a second top surface of the trap nitride of the first ONO layer.

7. The semiconductor device according to claim 1, wherein the third oxide includes a first top surface having a height substantially equal to a second top surface of the trap nitride of the second ONO layer.

8. The semiconductor device according to claim 1, wherein a spacing distance between the first ONO layer and the second ONO layer is between about 0.13 μm to about 0.26 μm.

9. The semiconductor device according to claim 1, wherein a spacing distance between the first ONO layer and the second ONO layer is about 0.13 μm.

10. The semiconductor device according to claim 1, wherein a spacing distance between the first ONO layer and the second ONO layer is about 0.26 μm.

11. A method for manufacturing a semiconductor device, including:
forming a first oxide-nitride-oxide (ONO) layer by stacking a block oxide, a tunnel oxide and a trap nitride over a semiconductor substrate;
separating the ONO layer into a first ONO layer and a second ONO layer by selectively etching the block oxide, the trap nitride and the tunnel oxide;
forming a third oxide between the first ONO layer and the second ONO layer;
forming a silicon gate over the first ONO layer, the second ONO layer and the third oxide; and
forming a source region and a drain region on a surface of the semiconductor substrate, on respective sides of the silicon gate.

12. The method according to claim 11, wherein forming the third oxide comprises:
forming the third oxide with a height higher than a height of the trap nitride of the first ONO layer and a height of the trap nitride of the second ONO layer.

13. The method according to claim 11, wherein forming the third oxide comprises:
forming the third oxide with a height substantially equal to a height of the trap nitride of the first ONO layer and a height of the trap nitride of the second ONO layer.

14. The method according to claim 11, wherein a spacing distance between the first ONO layer and the second ONO layer is between about 0.13 μm to about 0.26 μm.

15. The method according to claim 11, wherein a spacing distance between the first ONO layer and the second ONO layer is about 0.13 μm.

16. The method according to claim 11, wherein a spacing distance between the first ONO layer and the second ONO layer is about 0.26 μm.

17. A semiconductor device, including:
a oxide-nitride-oxide (ONO) layer in which a block oxide, a trap nitride, and a tunnel oxide are stacked sequentially over one side of a semiconductor substrate;
a second oxide-nitride-oxide (ONO) layer in which the block oxide, the trap nitride, and the tunnel oxide are stacked sequentially over another side of the semiconductor substrate;
a third oxide formed between the first ONO layer and the second ONO layer; and
a silicon gate formed over the first ONO layer, the second ONO layer and the third oxide.

18. The semiconductor device according to claim 17, comprising:
a source region and a drain region formed on a surface of the semiconductor substrate, on respective sides of the silicon gate.

19. The semiconductor device according to claim 17, wherein the third oxide is formed to be higher than, or substantially equal to, a height of the trap nitride of the first ONO layer and a height of the trap nitride of the second ONO layer.

20. The semiconductor device according to claim 17, wherein a spacing distance between the first ONO layer and the second ONO layer is between about 0.13 μm to about 0.26 μm.
